(19) United States
(12) Patent Application Publication
(10) Pub. No.: US 2026/0242937 A1
(43) Pub. Date: Aug. 20, 2026

(54) METHOD OF FORMING THIN FILM, AND SEMICONDUCTOR SUBSTRATE AND SEMICONDUCTOR DEVICE FABRICATED USING THE SAME

(71) Applicant: SOULBRAIN CO., LTD., Gyeonggi-do (KR)

(72) Inventors: Jae Sun JUNG, Gyeonggi-do (KR); Chang Bong YEON, Gyeonggi-do (KR); Ji Hyun NAM, Gyeonggi-do (KR); Deok-Hyun CHO, Gyeonggi-do (KR)

(21) Appl. No.: 19/159,341

(22) PCT Filed: Feb. 22, 2024
(86) PCT No.: PCT/KR2024/002311

§ 371 Date: Aug. 25, 2025

(30) Foreign Application Priority Data
Feb. 23, 2023 (KR) 10-2023-0024371
Apr. 12, 2023 (KR) 10-2023-0048191
Apr. 21, 2023 (KR) 10-2023-0052412
Oct. 31, 2023 (KR) 10-2023-0147439

(51) Int. Cl. C23C 16/34; C23C 16/44

(52) U.S. Cl. CPC C23C 16/34; C23C 16/4408

(57) ABSTRACT

The present invention relates to a method of forming a thin film, and a semiconductor substrate and semiconductor device fabricated using the same. According to the method of the present invention, by applying a predetermined reducing agent, even in the case of forming a thin film on a substrate having a highly integrated or complex structure, the thickness uniformity of a thin film may be greatly improved, impurities may be reduced, and the density and resistivity of the thin film may be improved, thereby effectively improving film quality.

### TECHNICAL FIELD

The present invention relates to a method of forming a thin film and a semiconductor substrate and semiconductor device fabricated using the same. More particularly, according to the method of the present invention, by applying a predetermined reducing agent, a reduction effect may be provided at a relatively low process temperature at which a precursor is not thermally decomposed. Accordingly, even in the case of forming a thin film on a substrate having a highly integrated or complex structure, the thickness uniformity of the thin film may be greatly improved, impurities may be significantly reduced, and the film quality may be improved.

### BACKGROUND ART

As the performance sophistication and high integration degree of semiconductor devices are required, electrode materials or diffusion barrier materials with reduced resistivity are demanded.

These materials are provided in the form of thin films through an atomic layer deposition (ALD) process, and in the reduction process used for forming the thin film, either a very strong reducing agent or high thermal energy is required.

However, very strong reducing agents such as N₂H₄ hydrazine are highly toxic and hazardous, resulting in handling issues, and when high thermal energy is applied, the precursor compound may undergo thermal decomposition, so that in highly integrated substrates or substrates with high aspect ratios and complex structures, step coverage may deteriorate, or voids and seams may occur.

In addition, impurities (C, Cl⁻, F⁻, etc.) derived from the ligands of the precursor compound may be introduced into the thin film, thereby not only contaminating the thin film but also disturbing the crystal arrangement, which reduces the density of the formed thin film, and thus may cause conductivity degradation problems attributable to low density.

Therefore, there is a need to develop a method for forming a thin film that may uniformly form a thin film having a complex structure, has a low residual amount of impurities, and greatly improves the thickness uniformity of the thin film, as well as a semiconductor substrate fabricated therefrom.

### RELATED ART DOCUMENTS

### Patent Documents

KR 2019-0141071 A

### DISCLOSURE

### Technical Problem

Therefore, the present invention has been made in view of the above problems, and it is one object of the present invention to provide a method of forming a thin film and a semiconductor substrate fabricated using the same. According to the method of the present invention, by applying a predetermined reducing agent, impurities may be reduced and resistivity may be improved, thereby effectively improving the thin film and deposition characteristics, so that even when a thin film is formed on a substrate having a complex structure, a high-quality thin film with uniform thickness may be formed.

It is another object of the present invention to improve film quality such as electrical characteristics, dielectric properties, and thin film density by using a predetermined reducing agent.

The above and other objects can be accomplished by the present invention described below.

### Technical Solution

In accordance with one aspect of the present invention, provided is a method of forming a thin film, the method including:
injecting a precursor compound into a chamber to adsorb the precursor compound onto a surface of a substrate; and injecting a reducing agent into the chamber to form a deposition film,
wherein the reducing agent: includes one or more selected from hydrogen iodide, hydrogen iodide water, hydrogen bromide, and hydrogen bromide water.

The reducing agent may be 3 N to 15 N hydrogen iodide, a gas mixture containing 1 to 99% by weight of 3 N to 15 N hydrogen iodide and a residual amount (amount that makes a total amount 100% by weight) of an inert gas, or an aqueous solution mixture containing 0.5 to 70% by weight of 3 N to N hydrogen iodide and a residual amount (amount that makes a total amount 100% by weight) of water. Here, the inert gas may be nitrogen, helium, or argon having a purity of 4 N to 9 N.

The thin film may be a laminated film containing one or more selected from the group consisting of Al, Cu, Au, Mo, Ag, W, Pt, Ta, Co, Ru, and Ti.

The thin film may be a nitride film, a metal film, or a selective thin film thereof formed on an entire substrate or a part of the substrate.

The precursor compound may be a molecule composed of one or more selected from the group consisting of Al, Cu, Au, Mo, Ag, W, Pt, Ta, Co, Ru, and Ti, and may be a compound having a vapor pressure of more than 0.01 mTorr and 100 Torr or less at 25° C.

The method of forming a thin film may include injecting a precursor compound into a chamber to adsorb the precursor compound onto a surface of a substrate; performing first purging of the inside of the chamber with a purge gas; injecting the reducing agent into the chamber to reduce the adsorbed precursor compound; and performing second purging of the inside of the chamber with a purge gas.

The method of forming a thin film may further include injecting a nitriding agent or an additional reaction gas into the chamber to form a nitride film.

The chamber may be an ALD chamber, a CVD chamber, a PEALD chamber, or a PECVD chamber.

The substrate loaded into the chamber may be heated to 100 to 800° C.

The nitriding agent may be ammonia or the like.

The additional reaction gas may be hydrogen or the like.

The thin film may be an aluminum metal film, a copper metal film, a gold metal film, a molybdenum metal film, a silver metal film, a tungsten metal film, a platinum metal film, a tantalum metal film, a cobalt metal film, a ruthenium metal film, a titanium metal film, an aluminum nitride film, a copper nitride film, a gold nitride film, a molybdenum nitride film, a silver nitride film, a tungsten nitride film, a platinum nitride film, a tantalum nitride film, a cobalt nitride film, a ruthenium nitride film, or a titanium nitride film.

In accordance with another aspect of the present invention, provided is a semiconductor substrate fabricated using the method described above.

The thin film may have a multilayer structure of 2 or 3 layers.

In accordance with yet another aspect of the present invention, provided is a semiconductor device including the semiconductor substrate described above.

### Advantageous Effects

According to the present invention, the present invention has an effect of providing a method of forming a thin film. According to the method, by applying a predetermined reducing agent, a: reduction effect can be simultaneously provided at a process temperature at which a precursor is not thermally decomposed, so that even when forming a thin film on a substrate having a highly integrated or complex structure, a uniform thin film can be formed, and impurities and film quality can be improved, thereby enabling the formation of a high-quality thin film.

In addition, process by-products that cause corrosion or deterioration of properties during thin film formation can be more effectively reduced. Furthermore, by modifying the film quality and improving the crystallinity of the thin film, the electrical characteristics of the thin film can be enhanced. In addition, the present invention has an effect of providing a method of forming a thin film and a semiconductor substrate fabricated using the same.

### DESCRIPTION OF DRAWINGS

FIG. 1 is a graph showing the AES analysis results according to temperature in Example 5 of the present invention.

FIG. 2 includes an XRD analysis graph according to process temperature for Example 5 of the present invention and conventional Comparative Example 3, and a graph confirming the impurity contents such as carbon, nitrogen, and oxygen in Example 2 and conventional Comparative Example 1.

FIG. 3 is an XRD analysis graph in Example 6 of the present invention and conventional Comparative Example 4.

### BEST MODE

Hereinafter, a method of forming a thin film according to the present invention and a semiconductor substrate fabricated using the method are described in detail.

In the present disclosure, unless otherwise specified, the term “reducing agent” refers to a substance capable of providing a film quality improvement effect by substituting the ligand of a precursor compound.

In the present disclosure, unless otherwise specified, the term “modification” refers to the positive interaction of a substance other than a precursor and reactant on a reaction surface to improve film quality, such as reducing resistivity, increasing density, and reducing impurities, in a deposited thin film.

The present inventors confirmed that, when a predetermined reducing agent capable of serving as a reducing agent at a relatively low process temperature at which a precursor is not thermally decomposed was used for a precursor compound adsorbed on the surface of a substrate loaded inside a chamber, it was confirmed that film quality such as electrical characteristics, dielectric properties, and thin film density was improved while preventing and suppressing the introduction of impurities. Based on these results, the present inventors conducted further studies to complete the present invention.

For example, the thin film may be provided with one or more precursors selected from the group consisting of Al, Cu, Au, Mo, Ag, W, Pt, Ta, Co, Ru, and Ti, and may provide a nitride film or a metal film. In this case, the effects to be achieved by the present invention may be sufficiently obtained.

As a specific example, the thin film may have a film composition of a tungsten film, a ruthenium film, a copper film, a rhodium film, a molybdenum nitride film, a tungsten nitride film, or a titanium nitride film.

The thin film may contain the aforementioned film composition alone or in a selective area, but is not limited thereto, and also includes SiH and SiOH.

The thin film may be utilized in a semiconductor device for purposes such as a commonly used diffusion barrier film or electrode film.

The thin film may be a laminated film containing one or more selected from the group consisting of Al, Cu, Au, Mo, Ag, W, Pt, Ta, Co, Ru, and Ti.

The precursor compound used for forming a thin film in the present invention may be a precursor compound used for purposes such as metal wiring or diffusion barrier.

For example, the precursor compound may have Al, Cu, Au, Mo, Ag, W, Pt, Ta, Co, Ru, or Ti as a central metal atom (M), and may have a structure in which ligands (L1, L2, L3, L4, L5, L6, etc.) are bonded.

As a specific example, the precursor compound may be a molecule having Al, Cu, Au, Mo, Ag, W, Pt, Ta, Co, Ru, or Ti as a central metal atom (M) and having one or more ligands selected from C, N, O, H, and X (halogen). In the case of a precursor having a vapor pressure of 0.01 mTorr to 100 Torr at 25° C., the effect used as the reducing agent may be maximized.

For example, when the central metal is divalent, L1 and L2 may be attached to the central metal as ligands. When the central metal is hexavalent, L1, L2, L3, L4, L5, and L6 may be attached to the central metal. The ligands corresponding to L1 to L6 may be the same or different.

For example, L1, L2, L3, L4, L5, and L6 may be the same or different as —H or —R, where —R may be a C1-C10 alkyl, a C1-C10 alkene, or a C1-C10 alkane, and may be linear or cyclic, and depending on the oxidation state of the central metal, the number n of L in L1, L2, L3, and L4 may be from 2 to 6.

For example, when the central metal is divalent, L1 and L2 may be attached to the central metal as ligands. When the central metal is hexavalent, L1, L2, L3, L4, L5, and L6 may be attached to the central metal. The ligands corresponding to L1 to L6 may be the same or different.

As a specific example, L1, L2, L3, L4, L5, and L6 may be the same or different as —H, —OR, or —NR₂, where —R may be H, a C1-C10 alkyl, a C1-C10 alkene, a C1-C10 alkane, iPr, or tBu. In this case, an appropriate reaction energy to be substituted by a reducing agent described later may be obtained.

As a specific example, L1, L2, L3, L4, L5, and L6 may be the same or different as —H or —X, where —X may be F, Cl, Br, or I. In this case, an appropriate reaction energy to be substituted by a reducing agent described later may be obtained.

As a specific example, L1, L2, L3, L4, L5, and L6 may be the same or different as —H or —R, where —R may be a C1-C10 alkyl, a C1-C10 alkene, or a C1-C10 alkane, and may have a linear or cyclic structure. In this case, an appropriate reaction energy to be substituted by a reducing agent described later may be obtained.

As a specific example, L1, L2, L3, L4, L5, and L6 may be the same or different as —H, —OR, or —NR₂, where —R may be H, a C1-C10 alkyl, a C1-C10 alkene, a C1-C10 alkane, iPr, or tBu. In this case, an appropriate reaction energy to be substituted by a reducing agent described later may be obtained.

As a specific example, L1, L2, L3, L4, L5, and L6 may be the same or different as —H or —X, where —X may be F, Cl, Br, or I. In this case, an appropriate reaction energy to be substituted by a reducing agent described later may be obtained.

Specifically, the precursor compound having molybdenum (Mo) as a central metal may be at least one selected from compounds having a structure represented by Chemical Formulas 1 and 2, and may include a trimethylene methane ligand and a derivative thereof, without being limited thereto.

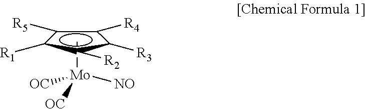

(In Chemical Formula 1, R1 to R5 are independently selected from hydrogen, an amino group, a silyl group, a C1-C8 alkyl group, and a C6-C8 aryl group, and the case where R1 to R5 are all hydrogen at the same time is excluded.)

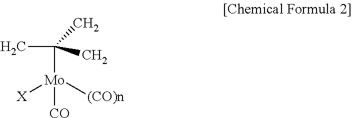

(In Chemical Formula 2, X includes H; F; Cl; Br; I; NO; CN; amidinate; guanidinate; ethylenediamine; propylenediamine; —NR6R7; —OR8; R9Cp; and a linear, branched, or cyclic, saturated or unsaturated hydrocarbon substituted with one or more of carbon (C), nitrogen (N), oxygen (O), phosphorus (P), and sulfur(S), R6, R7, R8, and R9 are independently selected from hydrogen, a C1-C12 alkyl group, and a C6-C12 aryl group, and n is an integer of 0 to 2.)

For example, the derivative of the trimethylene methane ligand may include a structure having a tribenzylidene methane ligand, a dibenzylidene methane ligand, and the like.

For example, the precursor compound having molybdenum (Mo) as a central metal may include Mo(CO)₆, (ethylbenzene)₂Mo, (2,6-diisopropylaniline)Mo(CO)₃, (1,4-diisopropyl-1,4-diazabutadiene)Mo(CO), Mo(CO)₅PCl₂Me, molybdenum acetate dimer, (ethylbenzene)Mo(allyl)₂, MeCpMo(CO)₂(allyl), iprCpMo(CO)₂(allyl), Mo(thd)₃, (MeCp)Mo(EMA)₃, (tert-butylimido)Mo(MeCp)₂, TDMAMo, Cp2MoH2, Mo(dithiocabate)₄, (tert-butylimido)₂MoCl(aminothiolate), (tert-butylimido)₂Mo(tert-butylthiol)(aminothiolate), (tertbutylimido)₂Mo(aminothiolate)₂, (tert-butylimido)₂Mo(tert-butylthiol)₂, (tert-butylimido)₂Mo(tert-butylamine)₂, (tert-butylimido)₂Mo(CpEMA), MoO₂(ipr-amidinate)₂, (tert-butylimido)₂Mo(ipr-amidinate)₂, (tert-butylimido)₂Mo(tert-butoxy)₂, (tert-butylimido)₂ Mo(N,N-dimethyldiethylene triamine), (tert-butylimido)₂ Mo(hydrazido)Cl, MoO₂(Dithiocarbamate)₂, (1,4-ditert-butyl-1,4,diazabutadiene)Mo(tert-butylimido)₂, MoO₂Cl₂, and the like.

Here, MoO₂Cl₂, (ethylbenzene)₂MO, (2,6-diisopropylaniline)Mo(CO)₃, (benzene)Mo(CO)₃, and 1,4-diisopropyl-1,4-diazabutaiene)Mo(CO)₃ may be compounds represented by Chemical Formulas 3-1 to 3-5, respectively.

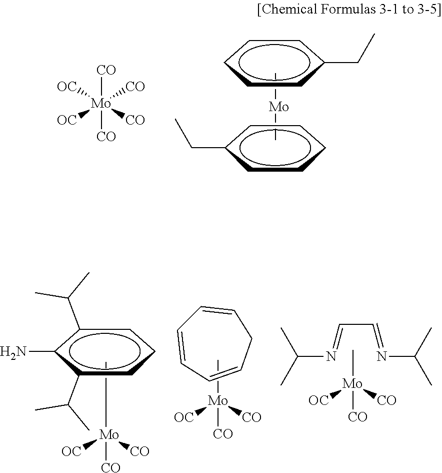

Here, Mo(CO)₅PCl₂Me, molybdenum acetate dimer, (ethylbenzene)Mo(allyl)₂, MeCpMo(CO)₂(allyl), and iprCpMo(CO)₂(allyl) may be compounds represented by Chemical Formulas 3-6 to 3-10 below, respectively.

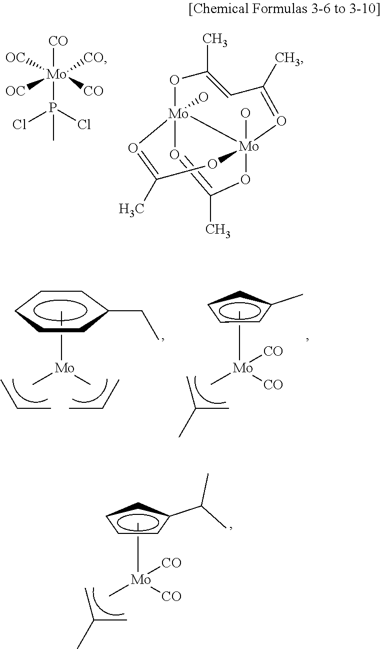

Here, Mo(thd)₃, (MeCp)Mo(EMA)₃, (tert-butylimido) Mo (MeCp)₂, TDMAMO, and Cp₂MoH₂ may be compounds represented by compounds represented by below, respectively.

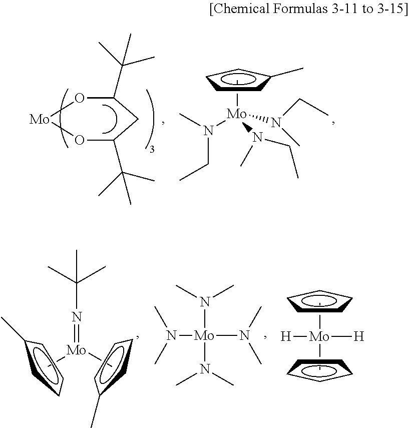

Here, Mo(dithiocabate)₄, (tert-butylimido)₂MoCl (aminothiolate), (tert-butylimido)₂Mo(tert-butylthiol)(aminothiolate), (tertbutylimido)₂Mo(aminothiolate)₂, and (tert-butylimido)₂Mo(tert-butylthiol)₂ may be compounds represented by Chemical Formulas 3-16 to 3-20 below, respectively.

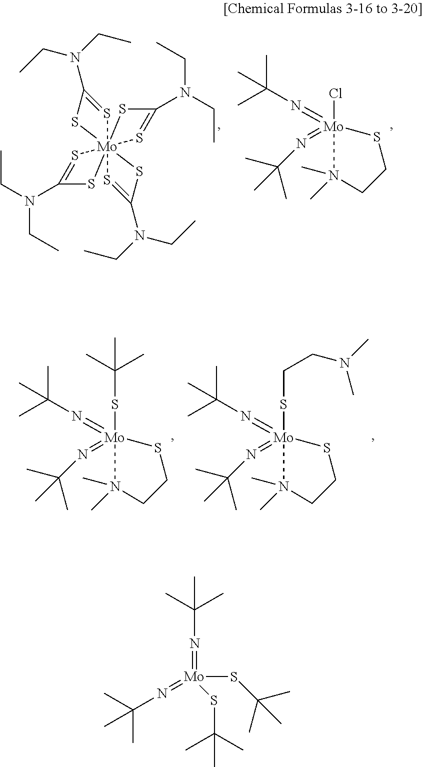

Here, (tert-butylimido)₂Mo(tert-butylamine)₂, (tert-butylimido)₂Mo(CpEMA), MoO₂(ipr-amidinate)₂, and (tert-butylimido)₂Mo (ipr-amidinate)₂ may be compounds represented by Chemical Formulas 3-20 to 3-24 below, respectively.

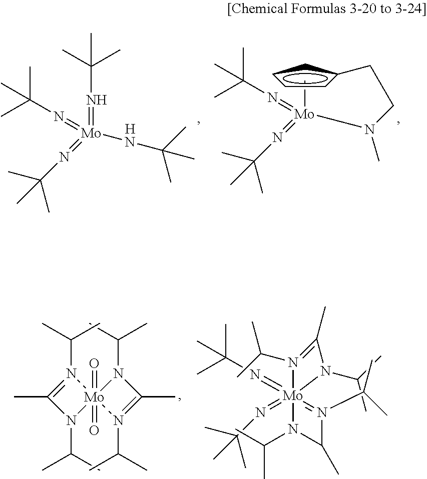

Here, (tert-butylimido)₂Mo(tert-butoxy)₂, (tert-butylimido)₂ Mo(N,N-dimethyldiethylene triamine), (tert-butylimido)₂ Mo(hydrazido)Cl, MoO₂(Dithiocarbamate)₂, 1,4-ditert-butyl-1,4, diazabutadiene)Mo(tert-butylimido)₂, MoO₂Cl₂, (tert-butylimido)₂Mo (dimethylamide)₂, and (Methylbenzene)₂Mo may be compounds represented by Chemical Formulas 3-25 to 3-31 below, respectively.

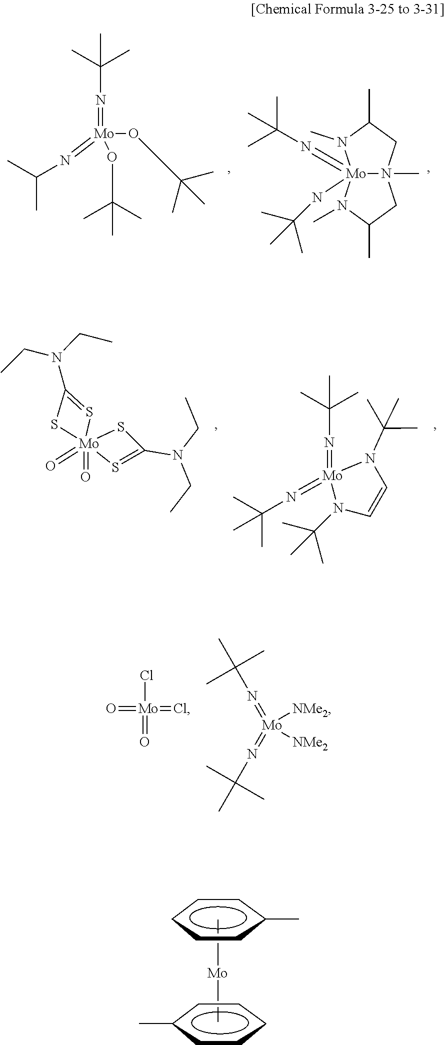

For example, the precursor compound may be mixed with a non-polar solvent and used. In this case, the viscosity or vapor pressure of the precursor compound may be easily controlled.

The reducing agent of the present invention may reduce the activation energy of the precursor compound adsorbed on the substrate to effectively substitute the ligands.

For example, the substitution of the ligands may be performed on the entire substrate or a part of the substrate where the thin film is formed by using the reducing agent, when necessary, a nitriding agent described later, or an additional reaction gas.

The reducing agent may include one or more selected from hydrogen iodide, hydrogen iodide water, hydrogen bromide, and hydrogen bromide water. In this case, the role of the reducing agent may be sufficiently performed at a relatively low process temperature, thereby suppressing side reactions during thin film formation. In addition, process by-products in the thin film may be reduced, so that corrosion or deterioration may be decreased, and improvements in film quality, such as enhancement of the crystallinity of the thin film, may be achieved. In addition, even when forming a thin film on a substrate having a highly integrated or complex structure, the thickness uniformity of a thin film may be greatly improved.

As a specific example, the reducing agent may be 3 N to 15 N hydrogen iodide, a gas mixture containing 1 to 99% by weight of 3 N to 15 N hydrogen iodide and a residual amount (amount that makes a total amount 100% by weight) of an inert gas, or an aqueous solution mixture containing 0.5 to 70% by weight of 3 N to 15 N hydrogen iodide and a residual amount (amount that makes a total amount 100% by weight) of water. Here, when the inert gas is nitrogen, helium, or argon having a purity of 4 N to 9 N, process by-products may be significantly reduced, and thin film density and the electrical characteristics of a thin film may be further improved.

Preferably, the reducing agent is 5 N to 6 N hydrogen iodide, a gas mixture containing 1 to 99% by weight of 5 N to 6 N hydrogen iodide and a residual amount (amount that makes a total amount 100% by weight) of an inert gas, or an aqueous solution mixture containing 0.5 to 70% by weight of 5 N to 6 N hydrogen iodide and a residual amount (amount that makes a total amount 100% by weight) of water. Here, the inert gas may be nitrogen, helium, or argon having a purity of 4 N to 9 N. In this case, side reactions may be suppressed during thin film formation, and thin film growth rate may be adjusted. Thus, process by-products in the thin film may be reduced, so that corrosion or deterioration may be decreased, and improvements in film quality, such as enhancement of the crystallinity of the thin film, may be achieved. In addition, even when forming a thin film on a substrate having a highly integrated or complex structure, the thickness uniformity of a thin film may be greatly improved.

The reducing agent is preferably 5 N to 6 N hydrogen iodide, a gas mixture containing 1 to 99% by weight of 5 N to 6 N hydrogen iodide and a residual amount (amount that makes a total amount 100% by weight) of an inert gas, or an aqueous solution mixture containing 0.5 to 70% by weight of 5 N to 6 N hydrogen iodide and a residual amount (amount that makes a total amount 100% by weight) of water. Here, the inert gas may be nitrogen, helium, or argon having a purity of 4 N to 9 N.

In this case, by sufficiently providing a reduction effect to the precursor compound adsorbed on the substrate at a relatively low process temperature at which a precursor is not thermally decomposed, when a thin film is formed on a substrate having a highly integrated or complex structure, the thickness uniformity of a thin film may be greatly improved. In addition to the thin film precursor, process by-products may be prevented from being adsorbed, thereby effectively protecting the surface of the substrate. In addition, the reaction rate may be reduced, and process by-products may be effectively removed.

The reducing agent may be preferably a compound having a purity of 99.9% or more, 99.95% or more, or 99.99% or more. For reference, when a compound having a purity of less than 99% is used, impurities may remain in a thin film or cause side reactions with precursors or reactants.

Accordingly, it is desirable to use a material having a purity of 99% or more.

For example, the thin film may contain a halogen compound in an amount of 100 ppm or less. For reference, when halogen excessively remains, when a nitriding agent described later is used under a temperature condition of 200 to 300° C., a chloride such as NH₄Cl may be generated and remain in the thin film, which is undesirable.

The thin film may be used for purposes such as an etch stop film or an electrode film, without being limited thereto.

In particular, as a relatively coarse thin film is formed, the growth rate of a thin film formed at the same time is greatly reduced, so that even when applied to a substrate having a complex structure, the uniformity of the thin film may be secured, and the thin film may be deposited in a thin thickness. In addition, the remaining amounts of O, Si, metals, and metal oxides remaining as process by-products may be improved. In addition, even the remaining amount of carbon, which was difficult to reduce in the past, may be improved.

The method of forming a thin film according to one embodiment of the present invention includes a step of injecting a precursor compound into a chamber to adsorb the precursor compound onto the surface of a substrate; and a step of injecting a reducing agent into the chamber to form a deposition film. Here, when one or more selected from hydrogen iodide, hydrogen iodide water, hydrogen bromide, and hydrogen bromide water is used as the reducing agent, the reduction of the precursor adsorbed on the substrate may be effectively performed at a relatively low process temperature at which the precursor is not thermally decomposed, thereby appropriately reducing the thin film growth rate. Thus, even in the case of forming a thin film on a substrate having a highly integrated or complex structure, the uniformity of the thin film may be greatly improved.

The reducing agent and precursor compound may be transferred into the chamber by a VFC method, a DLI method, or an LDS method.

The input amount (mg/cycle) ratio of the precursor compound to the reducing agent in the chamber may be 1:1 to 1:20.

In the step of injecting the reducing agent onto the surface of the substrate, the feeding time (sec) per cycle of the reducing agent onto the surface of the substrate may be preferably 0.01 to 10 seconds, more preferably 0.02 to 8 seconds, still more preferably 0.04 to 6 seconds, still more preferably 0.05 to 4 seconds. Within this range, the thin film growth rate may be reduced, and step coverage and cost efficiency may be excellent.

In the present disclosure, the feeding time of the reducing agent is based on a flow rate of 0.1 to 8,000 mg/cycle for a chamber volume of 15 to 20 L, more specifically, on a flow rate of 10 to 5,000 mg/cycle for a chamber volume of 18 L.

As a specific example, the method of forming a thin film may include a step of injecting a precursor compound into a chamber to adsorb the precursor compound onto the surface of a substrate; a step of performing first purging of the inside of the chamber with a purge gas; a step of injecting the reducing agent into the chamber to reduce the adsorbed precursor compound; and a step of performing second purging of the inside of the chamber with a purge gas.

The entire steps described above may be defined as a unit cycle (cycle), and the cycle may be repeatedly performed until a thin film having a desired thickness is obtained. In this way, when the reducing agent is sequentially introduced after the precursor compound within one cycle to improve the film quality, the generated process by-products may be effectively removed, thereby reducing the resistivity of the thin film, greatly improving step coverage, and enhancing the uniformity of the thin film. In addition, film quality such as electrical characteristics, dielectric properties, and thin film density may be improved.

The chamber may be an ALD chamber, a CVD chamber, a PEALD chamber, or a PECVD chamber.

The substrate loaded into the chamber may be heated to 100 to 800° C.

The reducing agent or precursor compound may be vaporized and injected, followed by a plasma post-treatment step. In this case, process by-products may be reduced while improving the growth rate of the thin film.

The method of forming a thin film according to another embodiment of the present invention includes a step of injecting a precursor compound into a chamber to adsorb the precursor compound onto the surface of a substrate; a step of injecting a reducing agent into the chamber to form a deposition film; and a step of injecting a nitriding agent or an additional reaction gas into the chamber to form a nitride film. In this case, the reduction of the precursor adsorbed on the substrate may be effectively performed, thereby appropriately reducing the thin film growth rate. Thus, even in the case of forming a thin film on a substrate having a highly integrated or complex structure, film quality such as electrical characteristics and thin film density may be greatly improved.

As a specific example, the method of forming a thin film may include a step of injecting a precursor compound into a chamber to adsorb the precursor compound onto the surface of a substrate; a step of performing first purging of the inside of the chamber with a purge gas; a step of injecting the reducing agent into the chamber to reduce the adsorbed precursor compound; a step of performing second purging of the inside of the chamber with a purge gas; a step of injecting a nitriding agent or an additional reaction gas into the chamber to form a thin film; and a step of performing third purging of the inside of the chamber with a purge gas.

The entire steps described above may be defined as a unit cycle (cycle), and the cycle may be repeatedly performed until a thin film having a desired thickness is obtained. In this way, when the reducing agent is sequentially introduced after the precursor compound within one cycle to improve the film quality, process by-products may be greatly reduced, and step coverage may be greatly improved. In addition, the crystallinity of the thin film may be increased, thereby reducing the resistivity of the thin film. In addition, even when applied to a semiconductor device having a high aspect ratio, the thickness uniformity of a thin film may be greatly improved, thereby ensuring the reliability of the semiconductor device. In addition, film quality such as electrical characteristics and thin film density may be improved.

The chamber may be an ALD chamber, a CVD chamber, a PEALD chamber, or a PECVD chamber.

The substrate loaded into the chamber may be heated to 100 to 800° C.

The nitriding agent may be nitrogen, ammonia, or the like.

The additional reaction gas may be hydrogen or the like.

In the present disclosure, the feeding time of the nitriding agent or additional reaction gas is based on a flow rate of 0.1 to 8,000 mg/cycle for a chamber volume of 15 to 20 L, more specifically, on a flow rate of 10 to 5,000 mg/cycle for a chamber volume of 18 L.

In the step of purging the unadsorbed precursor compound, the amount of purge gas injected into the ALD chamber is not particularly limited as long as the amount is sufficient to remove the unadsorbed precursor compound. For example, the amount may be 10 to 10,000 times, preferably 50 to 50,000 times, more preferably 100 to 10,000 times the volume of the precursor compound injected into the chamber. Within this range, by sufficiently removing the unadsorbed precursor compound, a thin film may be formed evenly and deterioration of film quality may be prevented. Here, the input amounts of the purge gas and precursor compound are each based on one cycle, and the volume of the precursor compound refers to the volume of the vaporized precursor compound vapor.

In addition, in the purging step performed immediately after the additional reaction gas supply step, the amount of purge gas introduced into the ALD chamber may be, for example, to 10,000 times, preferably 50 to 50,000 times, more preferably 100 to 10,000 times the volume of reaction gas introduced into the ALD chamber. Within this range, the desired effects may be sufficiently achieved. Here, the input amounts of purge gas and additional reaction gas are based on one cycle.

The reducing agent, precursor compound, nitriding agent, or additional reaction gas may preferably be transferred into the ALD chamber by a VFC method, a DLI method, or an LDS method, and more preferably, by a VFC method.

For example, the substrate loaded into the chamber may be heated to 100 to 800° C., as a specific example, 300 to 600° C. The reducing agent or precursor compound may be injected onto the substrate in an unheated or heated state, or may be injected unheated and then heated during the deposition process, depending on the deposition efficiency. For example, the reducing agent or precursor compound may be injected onto the substrate at 50 to 400° C. for 1 to 20 seconds.

The input amount (mg/cycle) ratio of the precursor compound to the reducing agent in the chamber may be preferably 1:1 to 1:20, more preferably 1:2 to 1:15, still more preferably 1:2 to 1:12, still more preferably 1:2.5 to 1:10. Within this range, step coverage may be improved, and process by-products may be greatly reduced.

For example, the method of forming a thin film may be performed at a deposition temperature of 100 to 800° C., preferably 300 to 600° C., more preferably 300 to 500° C., still more preferably 300 to 400° C. Within this range, a thin film with excellent film quality may be grown while implementing ALD process characteristics.

For example, the method of forming a thin film may be performed at a deposition pressure of 0.01 to 20 Torr, preferably 0.1 to 20 Torr, more preferably 0.1 to 10 Torr, most preferably 0.3 to 7 Torr. Within this range, a thin film having a uniform thickness may be obtained.

In the present disclosure, the deposition temperature and the deposition pressure may be measured as temperature and pressure formed within the deposition chamber, or as temperature and pressure applied to the substrate within the deposition chamber.

The method of forming a thin film may preferably include a step of increasing the temperature inside the chamber to a deposition temperature before introducing the precursor compound into the chamber; and/or a step of performing purging by injecting an inert gas into the chamber before introducing the precursor compound into the chamber.

In the method of forming a thin film, the residual halogen intensity (c/s) in the thin film may be preferably 100,000 or less, more preferably 70,000 or less, still more preferably 50,000 or less, still more preferably 10,000 or less, as a preferred example, 5,000 or less, still more preferably 10 to 4,000, still more preferably 10 to 3,000 as measured using a thin film having a thickness of 100 Å according to SIMS. Within this range, corrosion and deterioration may be effectively prevented.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the thin film growth rate per cycle may be appropriately controlled. In addition, since deposition is performed as an atomic mono-layer or nearly an atomic mono-layer, the film quality may be improved.

In addition, as a thin film manufacturing device capable of implementing the thin film manufacturing method, the present invention may include a thin film manufacturing device including an ALD chamber, a first vaporizer for vaporizing a precursor compound, a first transport means for transferring the vaporized precursor compound into the ALD chamber, a second vaporizer for vaporizing a reducing agent, a second transport means for transferring the vaporized reducing agent into the ALD chamber, and a third transport means for transferring a nitriding agent or an additional reaction gas into the ALD chamber. Here, vaporizers and transport means commonly used in the technical field to which the present invention pertains may be used in the present invention without particular limitation.

As a specific example, the method of forming a thin film is explained. First, a substrate on which a thin film is to be formed is placed in a deposition chamber capable of atomic layer deposition.

The substrate may include a semiconductor substrate, such as a silicon substrate or a silicon oxide substrate.

The substrate may further have a conductive layer or an insulating layer formed on the upper portion thereof.

To deposit a thin film on a substrate placed in the deposition chamber, the above-described reducing agent, precursor compound, or mixture of the precursor compound and the non-polar solvent are each prepared.

Next, the prepared precursor compound or a mixture of the precursor compound and a non-polar solvent (hereinafter referred to as composition for forming a thin film) is injected into the vaporizer, is transformed into a vapor phase, is transferred into the deposition chamber, and is adsorbed on the substrate. Then, the unadsorbed precursor compound or mixture of the precursor compound and a non-polar solvent is purged.

The non-polar solvent may preferably include one or more selected from the group consisting of alkanes and cycloalkanes. In this case, an organic solvent with low reactivity and solubility and easy moisture management may be included. In addition, step coverage may be improved even when deposition temperature increases during thin film formation.

As a preferred example, the non-polar solvent may include a C1 to C10 alkane or a C3 to C10 cycloalkane, preferably a C3 to C10 cycloalkane. In this case, reactivity and solubility may be low and moisture management may be easy.

In the present disclosure, C1, C3, and the like indicate the number of carbon atoms.

The cycloalkane may preferably include C3 to C10 monocycloalkanes, and among the monocycloalkanes, cyclopentane is liquid at room temperature and has the highest vapor pressure, so cyclopentane is preferable in the vapor deposition process, but the present invention is not limited thereto.

For example, the non-polar solvent may have a solubility (25° C.) of 200 mg/L or less, preferably 50 to 400 mg/L, more preferably 135 to 175 mg/L in water. Within this range, the reactivity toward the precursor compound may be reduced, and moisture may be easily managed.

In the present disclosure, solubility may be measured without any particular limitation by a measurement method or standard commonly used in the technical field to which the present invention pertains. For example, solubility may be measured by the HPLC method using a saturated solution.

Based on a total weight of the precursor compound and the non-polar solvent, the non-polar solvent may be included in an amount of 5 to 95% by weight, more preferably 10 to 90% by weight, still more preferably 40 to 90% by weight, most preferably 70 to 90% by weight.

When the content of the non-polar solvent exceeds the above range, impurities may be generated, which may increase the resistance and impurities within a thin film. When the content of the organic solvent is less than the range, the effect of improving step coverage due to solvent addition and the effect of reducing impurities such as chloride (Cl) ions may be reduced.

Next, the prepared reducing agent is injected into the vaporizer, is transformed into a vapor phase, is transferred into the deposition chamber, and is adsorbed. Then, the unadsorbed reducing agent is purged.

In the present disclosure, for example, the reducing agent and precursor compound (composition for forming a thin film) may be delivered into the deposition chamber by vapor flow control (VFC) using mass flow control (MFC) or a liquid delivery system (LDS) using liquid mass flow control (LMFC), preferably an VFC method.

At this time, a mixed gas of one or more selected from the group consisting of argon (Ar), nitrogen (N₂), and helium (He) may be used as a carrier gas or dilution gas to move the reducing agent and precursor compound onto the substrate, without being limited thereto.

In the present disclosure, for example, an inert gas, preferably the carrier gas or dilution gas may be used as the purge gas.

Next, when necessary, a nitriding agent or an additional reaction gas is supplied. The nitriding agent or additional reaction gas is not particularly limited as long as it is an additional reaction gas commonly used in the technical field to which the present invention pertains, and may preferably include a nitriding agent such as nitrogen gas (N₂), hydrazine gas (N₂H₄), or a mixture of nitrogen gas and hydrogen gas, and an additional reaction gas such as hydrogen gas (H₂).

The nitriding agent and the precursor compound adsorbed on the substrate react to form a nitride film.

The additional reaction gas and the precursor compound adsorbed on the substrate react to form a metal film.

Next, an inert gas is used to purge the unreacted residual nitriding agent or additional reaction gas. Accordingly, not only an excessive amount of the nitriding agent or additional reaction gas but also the by-products generated may be removed together.

In this way, for example, in the method of forming a thin film, a step of adsorbing a precursor compound/composition for forming a thin film on a substrate, a step of purging the unadsorbed precursor compound, a step of adsorbing a reducing agent on the substrate, a step of purging the unadsorbed reducing agent, a step of supplying a nitriding agent or an additional reaction gas when necessary, and a step of purging the residual nitriding agent or additional reaction gas when necessary may be set as a unit cycle, and the unit cycle may be repeated to form a thin film having a desired thickness.

For example, the unit cycle may be repeated 1 to 99,999 times, preferably 10 to 1,000 times, more preferably 50 to 5,000 times, still more preferably 100 to 2,000 times. Within this range, the desired thin film properties may be well expressed.

In addition, the present invention provides a semiconductor substrate, and the semiconductor substrate is fabricated by the thin film formation method. In this case, the thickness uniformity of a thin film may be excellent, and the density and electrical properties thereof may be excellent.

The manufactured thin film may preferably have a thickness of 30 nm or less, a resistivity value of 5 to 2,000 Ω·cm based on a thin film thickness of 10 nm, a halogen content of 10,000 ppm or less, and a step coverage of 90% or more. Within this range, the thin film has excellent performance as a diffusion barrier and has the effect of reducing corrosion of metal wiring materials, without being limited thereto.

For example, the thin film may have a thickness of 0.1 to 30 nm, preferably 1 to 20 nm, more preferably 2 to 10 nm. Within this range, thin film properties may be excellent.

For example, the thin film may have a resistivity value of 0.1 to 400 μΩ·cm, preferably 15 to 300 μΩ·cm, more preferably 20 to 290 μΩ·cm based on a thin film thickness of nm. Within this range, thin film properties may be excellent.

The thin film may have a halogen content of preferably 10,000 ppm or less or 1 to 9,000 ppm, still more preferably 5 to 8,500 ppm, still more preferably 100 to 1,000 ppm. Within this range, thin film properties may be excellent, and thin film growth rate may be reduced. Here, the halogen remaining in the thin film may be, for example, Cl₂, Cl, or Cl⁻. As the halogen residue within the thin film decreases, the film quality increases.

For example, the thin film may have a step coverage of 90% or more, preferably 92% or more, more preferably 95% or more. Within this range, since even a thin film of complex structure may be easily deposited on a substrate, the thin film may be applied to next-generation semiconductor devices.

Preferably, the manufactured thin film may have a thickness of 20 nm or less, a carbon, nitrogen, and halogen content of 10,000 ppm or less based on a thin film thickness of 10 nm, and a step coverage of 90% or more. Within this range, the thin film may have excellent performance as a dielectric film or blocking film, without being limited thereto.

Hereinafter, preferred examples and drawings are presented to help understand the present invention, but the following examples and drawings are only illustrative of the present invention, and it is obvious to those skilled in the art that various changes and modifications are possible within the scope and technical idea of the present invention. Such changes and modifications fall within the scope of the appended patent claims.

### EXAMPLES

### Example 1

An ALD deposition process was performed using 5N HI as a reducing agent and a BTBMMo precursor represented by Chemical Formula below as a precursor compound.

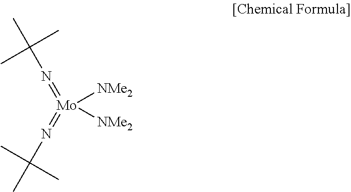

First, the prepared precursor compound was placed in a separate canister and supplied to a separate vaporizer heated to 150° C. at a flow rate of 0.1 g/min using a liquid mass flow controller (LMFC) at room temperature. Then, the BTBMMo precursor vaporized in a vapor phase in the vaporizer was injected into the deposition chamber for 3 seconds, and then argon gas was supplied at 5000 sccm for 10 seconds to perform argon purging. At this time, the pressure inside the reaction chamber was controlled to 2.5 Torr.

Next, the prepared reducing agent was placed in the canister and supplied to the chamber at a flow rate of 1000 sccm using a mass flow controller (MFC) at room temperature. Then, the reducing agent vaporized in a vapor phase in the vaporizer was injected into the substrate-loaded deposition chamber for 2 seconds, and then argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MON metal film), the thickness of the thin film deposited per cycle was calculated by dividing the measured thickness of the thin film by the number of cycles, and the result was 10 nm. The component analysis of the thin film was performed through AES and SIMS analyses. Then, sheet resistance was measured using the four-probe measurement method, and the resistivity value was calculated by using the measured thickness.

### Example 2

An ALD deposition process was performed using 5 N HI and NH₃ as reducing agents and a BTBMMo precursor represented by Chemical Formula below as a precursor compound.

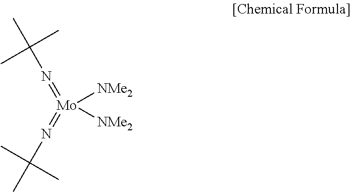

First, the prepared precursor compound was placed in a separate canister and supplied to a separate vaporizer heated to 150° C. at a flow rate of 0.1 g/min using a liquid mass flow controller (LMFC) at room temperature. Then, the BTBMMo precursor vaporized in a vapor phase in the vaporizer was injected into the deposition chamber for 3 seconds, and then argon gas was supplied at 5000 sccm for 10 seconds to perform argon purging. At this time, the pressure inside the reaction chamber was controlled to 2.5 Torr.

Next, the prepared HI reducing agent was placed in the canister and supplied to the chamber at a flow rate of 1000 sccm using a mass flow controller (MFC) at room temperature. Then, the reducing agent vaporized in a vapor phase in the vaporizer was injected into the substrate-loaded deposition chamber for 2 seconds, and then argon gas was supplied at 5000 sccm for 10 seconds to perform argon purging. Then, after supplying NH₃ as a reducing agent into the chamber at a flow rate of 1000 sccm, argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MON metal film), the thickness of the thin film deposited per cycle was calculated by dividing the measured thickness of the thin film by the number of cycles, and the result was 10 nm. The component analysis of the thin film was performed through AES and SIMS analyses. Then, sheet resistance was measured using the four-probe measurement method, and the resistivity value was calculated by using the measured thickness.

### Example 3

An ALD deposition process was performed using 5 N HI as a reducing agent and a BTBTBMo precursor represented by Chemical Formula below as a precursor compound.

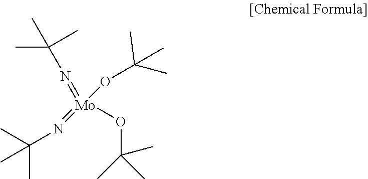

First, the prepared precursor compound was placed in a separate canister and supplied to a separate vaporizer heated to 150° C. at a flow rate of 0.1 g/min using a liquid mass flow controller (LMFC) at room temperature. After introducing the BTBTBMo precursor vaporized into a vapor phase in the vaporizer into the deposition chamber for 3 seconds, argon gas was supplied at 5000 sccm for 10 seconds to perform argon purging. At this time, the pressure inside the reaction chamber was controlled to 2.5 Torr.

Next, the prepared reducing agent was placed in the canister and supplied to the chamber at a flow rate of 1000 sccm using a mass flow controller (MFC) at room temperature. Then, the reducing agent vaporized in a vapor phase in the vaporizer was injected into the substrate-loaded deposition chamber for 2 seconds, and then argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MON metal film), the thickness of the thin film deposited per cycle was calculated by dividing the measured thickness of the thin film by the number of cycles, and the result was 10 nm. The component analysis of the thin film was performed through AES and SIMS analyses. Then, sheet resistance was measured using the four-probe measurement method, and the resistivity value was calculated by using the measured thickness.

### Example 4

An ALD deposition process was performed using 5 N HI and NH₃ as reducing agents and a BTBTBMo precursor represented by Chemical Formula below as a precursor compound.

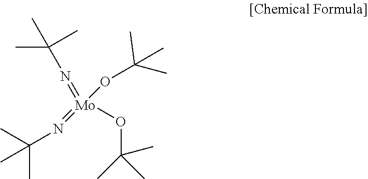

First, the prepared precursor compound was placed in a separate canister and supplied to a separate vaporizer heated to 150° C. at a flow rate of 0.1 g/min using a liquid mass flow controller (LMFC) at room temperature. After introducing the BTBTBMo precursor vaporized into a vapor phase in the vaporizer into the deposition chamber for 3 seconds, argon gas was supplied at 5000 sccm for 10 seconds to perform argon purging. At this time, the pressure inside the reaction chamber was controlled to 2.5 Torr.

Next, the prepared HI reducing agent was placed in the canister and supplied to the chamber at a flow rate of 1000 sccm using a mass flow controller (MFC) at room temperature. Then, the reducing agent vaporized in a vapor phase in the vaporizer was injected into the substrate-loaded deposition chamber for 2 seconds, and then argon gas was supplied at 5000 sccm for 10 seconds to perform argon purging. Then, after supplying NH₃ as a reducing agent into the chamber at a flow rate of 1000 sccm, argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MON metal film), the thickness of the thin film deposited per cycle was calculated by dividing the measured thickness of the thin film by the number of cycles, and the result was 10 nm. The component analysis of the thin film was performed through AES and SIMS analyses. Then, sheet resistance was measured using the four-probe measurement method, and the resistivity value was calculated by using the measured thickness.

### Example 5

An ALD deposition process was performed using 5 N HI as a reducing agent and Mo(CO)₆ precursor represented by Chemical Formula below as a precursor compound.

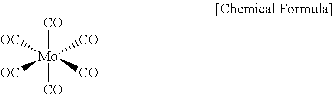

First, the prepared precursor compound was placed in a separate canister, heated to 50° C., and then the Mo(CO)₆ precursor was introduced into the deposition chamber for 3 seconds with an Ar carrier at 50 sccm. Then, argon gas was supplied at 5000 sccm for 10 seconds to perform argon purging. At this time, the pressure inside the reaction chamber was controlled to 2.5 Torr.

Next, the prepared reducing agent was placed in the canister and supplied to the chamber at a flow rate of 1000 sccm using a mass flow controller (MFC) at room temperature. Then, the reducing agent vaporized in a vapor phase in the vaporizer was injected into the substrate-loaded deposition chamber for 2 seconds, and then argon gas was supplied at 5000 sccm for 10 seconds to perform argon purging. At this time, the pressure inside the reaction chamber was controlled to 2.5 Torr. The deposition temperature was maintained at 375° C., and such a process was repeated 50 to 200 times to form a 10 nm thick self-limiting atomic layer thin film.

Using an ellipsometer which is a device capable of measuring optical properties such as thickness and refractive index of the thin film by using the polarization characteristics of light for the manufactured thin film (Mo metal film), the thickness of the thin film deposited per cycle was calculated by dividing the measured thickness of the thin film by the number of cycles, and the result was 10 nm. Sheet resistance was measured using the four-probe measurement method, and the resistivity value was calculated by using the measured thickness. The crystallinity of the Mo thin film was confirmed through XRD analysis.

### Example 6

An ALD deposition process was performed using 5 N HI as a reducing agent and Mo(tol)₂ precursor represented by Chemical Formula below as a precursor compound.

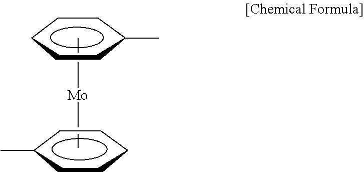

First, the prepared precursor compound was placed in a separate canister, heated to 130° C., and then the Mo(tol)₂ precursor was introduced into the deposition chamber for 10 seconds with an Ar carrier at 50 sccm. Then, argon gas was supplied at 5000 sccm for 10 seconds to perform argon purging. At this time, the pressure inside the reaction chamber was controlled to 2.5 Torr.

Next, the prepared reducing agent was placed in the canister and supplied to the chamber at a flow rate of 1000 sccm using a mass flow controller (MFC) at room temperature. Then, the reducing agent vaporized in a vapor phase in the vaporizer was injected into the substrate-loaded deposition chamber for 2 seconds, and then argon gas was supplied at 5000 sccm for 10 seconds to perform argon purging. At this time, the pressure inside the reaction chamber was controlled to 2.5 Torr. The deposition temperature was maintained at 250° C., and such a process was repeated 30 to 300 times to form a 10 nm thick self-limiting atomic layer thin film.

Using an ellipsometer which is a device capable of measuring optical properties such as thickness and refractive index of the thin film by using the polarization characteristics of light for the manufactured thin film (Mo metal film), the thickness of the thin film deposited per cycle was calculated by dividing the measured thickness of the thin film by the number of cycles, and the result was 10 nm. Sheet resistance was measured using the four-probe measurement method, and the resistivity value was calculated by using the measured thickness.

### COMPARATIVE EXAMPLES

### Comparative Example 1

An ALD deposition process was performed using NH₃ as a reducing agent and a BTBMMo precursor represented by Chemical Formula below as a precursor compound.

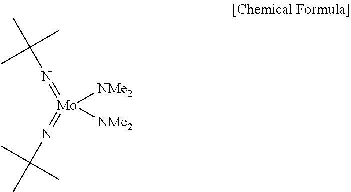

First, the prepared precursor compound was placed in a separate canister and supplied to a separate vaporizer heated to 150° C. at a flow rate of 0.1 g/min using a liquid mass flow controller (LMFC) at room temperature. Then, the BTBMMo precursor vaporized in a vapor phase in the vaporizer was injected into the deposition chamber for 3 seconds, and then argon gas was supplied at 5000 sccm for 10 seconds to perform argon purging. At this time, the pressure inside the reaction chamber was controlled to 2.5 Torr.

Subsequently, the prepared reducing agent NH₃ was supplied into the chamber at a flow rate of 1,000 sccm. After introducing the reducing agent vaporized into a vapor phase in the vaporizer into the substrate-loaded deposition chamber for 2 seconds, argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MON metal film), the thickness of the thin film deposited per cycle was calculated by dividing the measured thickness of the thin film by the number of cycles, and the result was 10 nm. The component analysis of the thin film was performed through AES and SIMS analyses. Then, sheet resistance was measured using the four-probe measurement method, and the resistivity value was calculated by using the measured thickness.

### Comparative Example 2

An ALD deposition process was performed using NH₃ as a reducing agent and a BTBTBMo precursor represented by Chemical Formula below as a precursor compound.

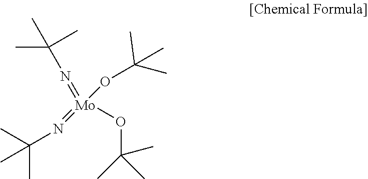

First, the prepared precursor compound was placed in a separate canister and supplied to a separate vaporizer heated to 150° C. at a flow rate of 0.1 g/min using a liquid mass flow controller (LMFC) at room temperature. After introducing the BTBTBMo precursor vaporized into a vapor phase in the vaporizer into the deposition chamber for 3 seconds, argon gas was supplied at 5000 sccm for 10 seconds to perform argon purging. At this time, the pressure inside the reaction chamber was controlled to 2.5 Torr.

Subsequently, the prepared reducing agent NH₃ was supplied into the chamber at a flow rate of 1,000 sccm. After introducing the reducing agent vaporized into a vapor phase in the vaporizer into the substrate-loaded deposition chamber for 2 seconds, argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MON metal film), the thickness of the thin film deposited per cycle was calculated by dividing the measured thickness of the thin film by the number of cycles, and the result was 10 nm. The component analysis of the thin film was performed through AES and SIMS analyses. Then, sheet resistance was measured using the four-probe measurement method, and the resistivity value was calculated by using the measured thickness.

### Comparative Example 3

An ALD deposition process was performed using NH₃ as a reducing agent and an Mo(CO)₆ precursor represented by Chemical Formula below as a precursor compound.

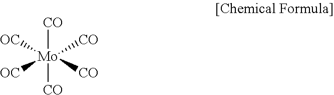

First, the prepared precursor compound was placed in a separate canister, heated to 50° C., and then the Mo(CO)₆ precursor was introduced into the deposition chamber for 3 seconds with an Ar carrier at 50 sccm. Then, argon gas was supplied at 5000 sccm for 10 seconds to perform argon purging. At this time, the pressure inside the reaction chamber was controlled to 2.5 Torr.

Subsequently, the prepared reducing agent NH₃ was supplied into the chamber at a flow rate of 1,000 sccm. After introducing the reducing agent vaporized into a vapor phase in the vaporizer into the substrate-loaded deposition chamber for 2 seconds, argon gas was supplied at 5000 sccm for 10 seconds to perform argon purging. At this time, the pressure inside the reaction chamber was controlled to 2.5 Torr. The deposition temperature was maintained at 375° C., and such a process was repeated 50 to 200 times to form a 10 nm thick self-limiting atomic layer thin film.

Using an ellipsometer which is a device capable of measuring optical properties such as thickness and refractive index of the thin film by using the polarization characteristics of light for the manufactured thin film (Mo metal film), the thickness of the thin film deposited per cycle was calculated by dividing the measured thickness of the thin film by the number of cycles, and the result was 10 nm. Sheet resistance was measured using the four-probe measurement method, and the resistivity value was calculated by using the measured thickness. The crystallinity of the Mo thin film was confirmed through XRD analysis.

### Comparative Example 4

An ALD deposition process was performed using NH₃ as a reducing agent and an Mo(tol)₂ precursor represented by Chemical Formula below as a precursor compound.

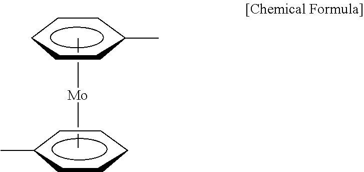

First, the prepared precursor compound was placed in a separate canister, heated to 130° C., and then the Mo(tol)₂ precursor was introduced into the deposition chamber for 10 seconds with an Ar carrier at 50 sccm. Then, argon gas was supplied at 5000 sccm for 10 seconds to perform argon purging. At this time, the pressure inside the reaction chamber was controlled to 2.5 Torr.

Subsequently, the prepared reducing agent NH₃ Was supplied into the chamber at a flow rate of 1,000 sccm. After introducing the reducing agent vaporized into a vapor phase in the vaporizer into the substrate-loaded deposition chamber for 2 seconds, argon gas was supplied at 5000 sccm for 10 seconds to perform argon purging. At this time, the pressure inside the reaction chamber was controlled to 2.5 Torr. The deposition temperatures were maintained at 250° C. and 300° C., respectively, and such a process was repeated 30 to 300 times to form a 10 nm thick self-limiting atomic layer thin film.

Using an ellipsometer which is a device capable of measuring optical properties such as thickness and refractive index of the thin film by using the polarization characteristics of light for the manufactured thin film (Mo metal film), the thickness of the thin film deposited per cycle was calculated by dividing the measured thickness of the thin film by the number of cycles, and the result was 10 nm. Sheet resistance was measured using the four-probe measurement method, and the resistivity value was calculated by using the measured thickness.

### TEST EXAMPLES

For each of the thin films of Examples 1 to 6 and Comparative Examples 1 to 4, the impurity content, the types and contents of elements constituting the material surface, the deposition rate, the crystal structure, and the orientation were analyzed and confirmed in the following manner.

*SIMS (Secondary-ion mass spectrometry) C impurities: By sputtering the thin film axially with ion sputtering, the C impurity value was confirmed from the SIMS graph by considering the C impurity content (counts) at a sputtering time of 50 seconds, when surface contamination of a substrate was minimal.

*AES (Auger electron spectroscopy): The types and contents of elements constituting the material surface were analyzed by irradiating the material surface with a focused electron beam and measuring the energy of the emitted Auger electrons.

*Deposition rate (GPC) measurement: For each of the thin films of Examples 1 to 6 and Comparative Examples 1 to 4, the deposition rate (GPC) was measured in the following manner. Specifically, the deposition rate of thin films having a thickness of 3 to 30 nm was measured using an ellipsometer, and the unit of Å/cycle was used.

*Grazing-incidence angle (incident angle, θ=3°) X-ray diffractometry: To confirm information such as crystal structure and orientation, diffraction analysis of the surface was performed using Cu-Kα X-ray.

TABLE 1

| | | BTBMMo | | |
|---|---|---|---|---|
| Precursor | | Comparative | | |
| Subjects | | Example 1 | Example 1 | Example 2 |
| Reducing agent | | NH₃ | HI | HI → NH₃ |
| Process temperature | | 350° C. | | |
| Deposition rate | | 0.7 | 0.3 | 0.3 |
| (Å/cycle) | | | | |
| Resistivity (μΩ · cm) | | ~1600 | 1672 | 1667 |
| Mo/N (AES) | | 1.3 | 0.9 | 0.9 |
| C impurities (AES) | | 28 | 0 | 0 |
| O impurities (AES) | | 9 | 13 | 10 |
| Density (g/cm³) | | 6.0 | 6.7 | 6.8 |
| SIMS | C⁻ | 46762 | — | 4054 |
| | CN⁻ | 10996 | — | 1177 |

As shown in Table 1, according to the present invention, when a single HI reducing agent process or a combined process of an HI reducing agent and NH₃ is used, it can be confirmed that the amount of C impurities generated when the NH₃ reducing agent is used alone is significantly reduced. In addition, as shown in Examples 1 and 2, it was confirmed from the AES analysis results that C impurities were reduced to 0% during thin film formation, and according to the SIMS results, the number of detected C ions was confirmed to be reduced by 91% or more.

In addition, since the thin film density increased from 6.0 to 6.8, it can be seen that a very high-quality MON thin film was formed.

TABLE 2

| | | BTBTBMo | | |
|---|---|---|---|---|
| Precursor | | Comparative | | |
| Subjects | | Example 2 | Example 3 | Example 4 |
| Reducing agent | | NH₃ | HI | HI → NH₃ |
| Process temperature | | 350° C. | | |
| Deposition rate | | ~0.55 | 0.3 | 0.5 |
| (Å/cycle) | | | | |
| Resistivity (μΩ · cm) | | ~2500 | ~1800 | ~1800 |
| Mo/N (AES) | | 0.7 | 1.0 | 0.9 |
| C impurities (AES) | | 0 | 0 | 0 |
| O impurities (AES) | | 21 | 18 | 12 |
| Density (g/cm³) | | 6.83 | 6.80 | 6.90 |
| SIMS | C⁻ | 11774 | 2934 | 4534 |
| | CN⁻ | 2817 | 708 | 1055 |

As shown in Table 2, according to the present invention, when a single HI reducing agent process or a combined process of an HI reducing agent and NH₃ is used, compared with the case of using the NH₃ reducing agent alone, the resistivity of the formed thin film was significantly reduced, and the C impurities were shown to decrease most effectively when only the HI reducing agent was used, in the order of Comparative Example 2>Example 4>Example 3.

TABLE 3

| | Mo (CO) ₆ | |
|---|---|---|
| Precursor | Comparative | |
| Subjects | Example 3 | Example 5 |
| Reducing agent | NH₃ | HI |
| Process temperature (° C.) | 375 | |
| Deposition rate (Å/cycle) | ~0.6 | ~1.8 |
| Resistivity (μΩ · cm) | 415 | 58 |

As shown in Table 3, according to the present invention, when the HI reducing agent is used, the resistivity of the formed thin film is significantly reduced compared with the case of using only the NH₃ reducing agent, and the deposition rate increased more than threefold. In particular, XRD analysis was performed according to process temperature, and the results are shown in FIG. 2. FIG. 2 is an XRD analysis graph according to process temperature between Example 5 of the present invention and Comparative Example 3.

As shown in FIG. 2 below, Example 5 shows that a pure Mo metal thin film was formed.

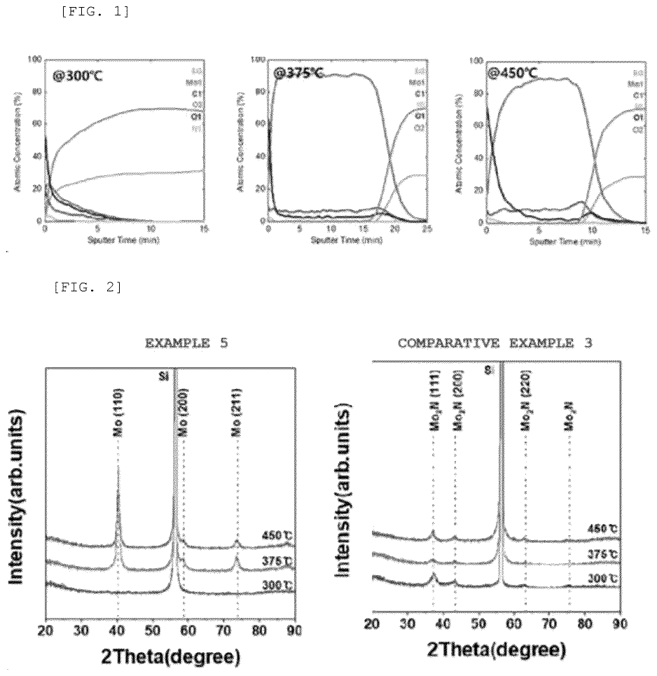

In addition, the AES analysis results according to temperature for Example 5 are shown in FIG. 1 below.

FIG. 1 is a graph showing the AES analysis results according to temperature in Example 5 of the present invention. As shown in FIG. 1 below, the types and content variations of the constituent elements according to process temperature were confirmed.

TABLE 4

| | Mo (tol) ₂ | | |
|---|---|---|---|
| Precursor | Comparative | | |
| Subjects | Example 4 | Example 6 | |
| Reducing agent | NH₃ | HI | HI |
| Process temperature | 250 | 250 | 300 |
| (° C.) | | | |
| Deposition rate | 0.37 | 0.83 | ~2.5 |
| (Å/cycle) | | | |
| Resistivity (μΩ · cm) | 22800 | 10900 | 800 |

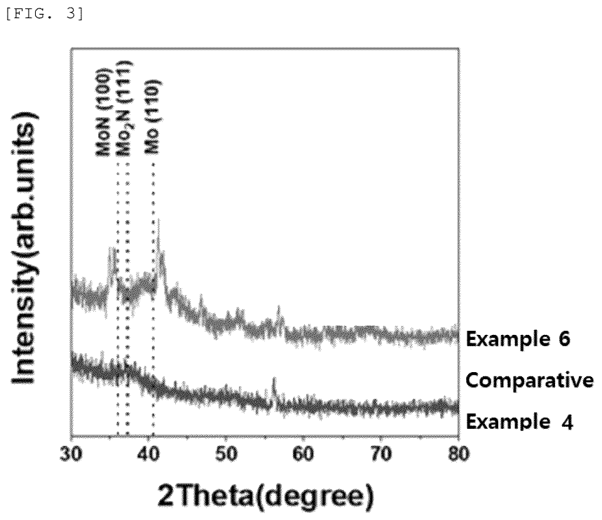

As shown in Table 4, according to the present invention, when the HI reducing agent is used, the resistivity of the formed thin film is significantly reduced compared with the case of using only the NH₃ reducing agent, and the deposition rate increased more than twofold. In particular, XRD analysis was performed, and the results are shown in FIG. 3. FIG. 3 is an XRD analysis graph between Example 6 of the present invention and Comparative Example 4.

As shown in FIG. 3 below, it can be seen that a pure Mo metal thin film was partially formed in Example 6.

In conclusion, by applying a predetermined reducing agent, even in the case of forming a thin film on a substrate having a highly integrated or complex structure, the thickness uniformity of a thin film may be greatly improved, impurities may be reduced, and the density and resistivity of the thin film may be improved, thereby effectively improving film quality.

1. A method of forming a thin film, comprising:
injecting a precursor compound into a chamber to adsorb the precursor compound onto a surface of a substrate; and injecting a reducing agent into the chamber to form a deposition film,
wherein the reducing agent comprises one or more selected from hydrogen iodide, hydrogen iodide water, hydrogen bromide, and hydrogen bromide water.
The method according to claim 1, wherein the reducing agent is 3 N to 15 N hydrogen iodide, a gas mixture containing 1 to 99% by weight of 3 N to 15 N hydrogen iodide and a residual amount (amount that makes a total amount 100% by weight) of an inert gas, or an aqueous solution mixture containing 0.5 to 70% by weight of 3 N to 15 N hydrogen iodide and a residual amount (amount that makes a total amount 100% by weight) of water,
wherein the inert gas is nitrogen, helium, or argon having a purity of 4 N to 9 N.

3. The method according to claim 1, wherein the thin film is a laminated film containing one or more selected from the group consisting of Al, Cu, Au, Mo, Ag, W, Pt, Ta, Co, Ru, and Ti.

4. The method according to claim 1, wherein the thin film is a nitride film, a metal film, or a selective thin film thereof formed on an entire substrate or a part of the substrate.

5. The method according to claim 1, wherein the precursor compound is a molecule composed of one or more selected from the group consisting of Al, Cu, Au, Mo, Ag, W, Pt, Ta, Co, Ru, and Ti, and is a compound having a vapor pressure of more than 0.01 mTorr and 100 Torr or less at 25° C.

6. The method according to claim 1, comprising injecting a precursor compound into a chamber to adsorb the precursor compound onto a surface of a substrate; performing first purging of the inside of the chamber with a purge gas; injecting the reducing agent into the chamber to reduce the adsorbed precursor compound; and performing second purging of the inside of the chamber with a purge gas.

7. The method according to claim 1 or 6, further comprising injecting a nitriding agent or an additional reaction gas into the chamber to form a nitride film.

8. The method according to claim 1, wherein the chamber is an ALD chamber, a CVD chamber, a PEALD chamber, or a PECVD chamber.

9. The method according to claim 1, wherein the substrate loaded into the chamber is heated to 100 to 800° C.

10. The method according to claim 1, wherein the thin film is an aluminum metal film, a copper metal film, a gold metal film, a molybdenum metal film, a silver metal film, a tungsten metal film, a platinum metal film, a tantalum metal film, a cobalt metal film, a ruthenium metal film, a titanium metal film, an aluminum nitride film, a copper nitride film, a gold nitride film, a molybdenum nitride film, a silver nitride film, a tungsten nitride film, a platinum nitride film, a tantalum nitride film, a cobalt nitride film, a ruthenium nitride film, or a titanium nitride film.

11. A semiconductor substrate fabricated using the method according to claim 1.

12. The semiconductor substrate according to claim 11, wherein the thin film has a multilayer structure of 2 or 3 layers.

13. A semiconductor device comprising the semiconductor substrate according to claim 11.
